(19) United States
(12) Patent Application Publication
(10) Pub. No.: US 2026/0237592 A1
(43) Pub. Date: Aug. 13, 2026

(54) METHOD FOR OPERATING A PARTICLE BEAM SYSTEM, AND PARTICLE BEAM SYSTEM

(71) Applicant: Carl Zeiss Microscopy GmbH, Jena (DE)

(72) Inventors: Christian Hendrich, Westhausen (DE); Joerg Fober, Heuchlingen (DE); Emanuel Heindl, Ellwangen (DE); Volker DREXEL, Koenigsbronn (DE)

(21) Appl. No.: 19/530,072

(22) Filed: Feb. 4, 2026

(30) Foreign Application Priority Data
Feb. 11, 2025 (DE) 10 2025 104 985.8

(51) Int. Cl. H01J 37/18; H01J 37/244; H01J 37/26

(52) U.S. Cl. CPC H01J 37/18; H01J 37/244; H01J 37/26; H01J 2237/1825; H01J 2237/24564

(57) ABSTRACT

A method of operating a particle beam system comprises, in a first operating mode, evacuating a sample space, operating a first ion getter pump and a second ion getter pump with a common high-voltage source for evacuating a source space and an intermediate vacuum space, measuring a current supplied from the high-voltage source to the first and second ion getter pumps, and determining the pressure in the intermediate vacuum space on the basis of the measured current. The method comprises, in a second operating mode, evacuating the sample space, operating the first ion getter pump with the high-voltage source for evacuating the source space without operating the second ion getter pump with the high-voltage source, measuring a current supplied from the high-voltage source to the first ion getter pump, and determining the pressure in the source space on the basis of the measured current.

### CROSS-REFERENCE TO RELATED APPLICATION

This application claims benefit under 35 U.S.C. § 119 to German Application No. 10 2025 104 985.8, filed Feb. 11, 2025. The entire disclosure of this application is incorporated by reference herein.

### FIELD

The present disclosure relates to a method for operating a particle beam system, and to a particle beam system.

### BACKGROUND

In a particle beam system, such as for example an electron beam microscope, a particle beam generated by a particle beam source is directed onto a sample in order to examine a sample. In order to enable operation of the particle beam source and in order furthermore to prevent contamination of the particle beam source, a vacuum system is provided which generates a high vacuum or ultra-high vacuum in a source space, in which the particle beam source is arranged. For this purpose, the vacuum system comprises for example an ion getter pump.

On the other hand, a sample space, in which the sample is arranged, is exposed to constant increases in gas pressure, which is why a significantly higher gas pressure is maintained by the vacuum system in the sample space compared to the source space. On account of the large pressure difference between the source space and the sample space, an intermediate vacuum space is provided, in which a further ion getter pump of the vacuum system generates a vacuum with a gas pressure which lies between the gas pressure of the vacuum in the source space and the gas pressure of the vacuum in the sample space.

Ion getter pumps are operated by a high-voltage source and ionize gas particles that are electromagnetically attracted by electrodes in the ion getter pump and are held there. An operating current of ion getter pumps is approximately proportional to a gas pressure in the ion getter pump. Therefore, in particle beam systems, a gas pressure in the source space is determined by a current supplied to the ion getter pump at the source space, and a gas pressure in the intermediate vacuum space is determined by a current supplied to the further ion getter pump at the intermediate vacuum space.

In general, a vacuum system of the particle beam system is a relatively elaborate system comprising a relatively large number of expensive components that are procured, assembled, and maintained.

### SUMMARY

The present disclosure to propose a particle beam system with a simplified vacuum system.

A particle beam system which can be used in a method proposed below can comprise a particle beam source, an evacuable source space, an evacuable sample space, an evacuable intermediate vacuum space, a first ion getter pump for evacuating the source space, a second ion getter pump for evacuating the intermediate vacuum space, and a high-voltage source. In this case, the intermediate vacuum space is separated from the source space and is connected thereto via a first opening, and is separated from the sample space and is connected thereto via a second opening, wherein in a measurement method a particle beam generated by the particle beam source and directed onto a sample arranged in the sample space passes through the first and second openings.

In this case, it should be noted that an evacuable space is one in which removal of gas from the space causes a reduction in the gas pressure in the space. Furthermore, hereinafter the terms “connection” and “connected” relate to the fact that gas can flow through the connection. For example, connections between vacuum spaces relate to a gas flow from one vacuum space into another vacuum space. In particular, one vacuum space is separated from another vacuum space if no gas or little gas compared to a volume of the vacuum space can flow into the other vacuum space. Two vacuum spaces are connected via an opening if gas can flow through the opening from one vacuum space into the other. Signal and current lines are referred to here as electrical connection.

A method proposed herein comprises a first operating mode and a second operating mode. The first operating mode comprises evacuating the sample space, operating the first ion getter pump and the second ion getter pump with a common high-voltage source in order to evacuate the source space and the intermediate vacuum space, or keep them evacuated, so that a pressure in the source space is lower than a pressure in the intermediate vacuum space and that the pressure in the intermediate vacuum space is lower than a pressure in the sample space, and measuring a current supplied from the high-voltage source to the first and second ion getter pumps, and determining a value representing the pressure in the intermediate vacuum space on the basis of the measured current. The second operating mode comprises evacuating the sample space, operating the first ion getter pump with the high-voltage source in order to evacuate the source space without operating the second ion getter pump with the high-voltage source, and measuring a current supplied from the high-voltage source to the first ion getter pump, and determining a value representing the pressure in the source space on the basis of the measured current.

For example, the above method makes it possible to operate both ion getter pumps jointly with a single high-voltage source, wherein recording the gas pressure in the source space and the intermediate vacuum space is furthermore possible. For example, the particle beam system can alternately switch between operating a single ion getter pump and operating both ion getter pumps. The vacuum generated in the source space has a significantly lower gas pressure than the vacuum in the intermediate vacuum space, which is why a current supplied to the ion getter pump at the intermediate vacuum space is significantly greater than a current supplied to the ion getter pump at the source space. If both ion getter pumps are operated jointly with the high-voltage source, the current supplied to the ion getter pump at the source space is accordingly negligibly low, whereby a current provided by the high-voltage source is substantially a current defined by the vacuum in the intermediate vacuum space. During such operation, a gas pressure in the intermediate vacuum space can thus be determined on the basis of the current provided by the high-voltage source. If only the ion getter pump at the source space is operated with the high-voltage source, the gas pressure in the source space can be determined from the current provided by the high-voltage source.

Since the ion getter pump at the intermediate vacuum space is switched off for this purpose, the measurement can be carried out within a relatively short time. Furthermore, the switching off of the ion getter pump at the intermediate vacuum space is influenced by the hardware used; for example, a current supplied to the ion getter pump at the intermediate vacuum space will not instantaneously drop to zero after the switching off. Accordingly, the determination of the gas pressure in the source space on the basis of the current provided by the high-voltage source can be carried out after a transition time period after which current is actually no longer supplied to the ion getter pump at the intermediate vacuum space. In addition, when the ion getter pump at the intermediate vacuum space is switched off, the gas pressure in the source space will increase within a relatively short time, since gas flows from the intermediate vacuum space into the source space. If the current supplied to the ion getter pump at the source space is recorded a number of times within a time period, an average value over such values can be formed in order to prevent fluctuations in the recorded value.

Such a method makes it possible to operate the vacuum system with a single high-voltage source for both ion getter pumps, whereby a relatively large number of components of the vacuum system can be obviated and a simplified vacuum system can be provided.

It should be noted that the current measured in the second operating mode can also be used to subtract a current supplied to the ion getter pump at the source space in the first operating mode from the total current provided by the high-voltage source or to eliminate a contribution of the ion getter pump at the source space.

In accordance with some embodiments, the method furthermore comprises opening a switch, so that the second ion getter pump is disconnected from the high-voltage source in the second operating mode, and closing the switch, so that the second ion getter pump is connected to the high-voltage source in the first operating mode. For example, a current supply to the ion getter pumps is controlled by a high-voltage controller comprising the high-voltage source and the switch that enables the second ion getter pump to be disconnected from the high-voltage source. For example, the switch can be a transistor.

In accordance with some embodiments, the particle beam system furthermore comprises a first valve provided in a vacuum connection between the intermediate vacuum space and a pump that evacuates the sample space, wherein the first valve is closed in the first operating mode and can be open in the second operating mode. For example, a further valve can be provided in a vacuum connection between the source space and the pump that evacuates the sample space, wherein the further valve is closed in both operating modes. Such valves are used primarily, before operation of the ion getter pumps starts, for example using a turbomolecular pump, to generate a vacuum in the source space and the intermediate vacuum space, the vacuum being presupposed by the ion getter pumps. After the turbomolecular pump has evacuated the source space and the intermediate vacuum space, the ion getter pumps are operated in the first operating mode and both valves are closed. In the second operating mode, however, the first valve can be opened in order to reduce a deterioration of the vacuum in the intermediate vacuum space, especially if the second operating mode is carried out for such a length of time that the gas pressure of the vacuum in the intermediate vacuum space would increase above a gas pressure of the vacuum appropriate for the second ion getter pump.

In accordance with some embodiments, determining the value representing the pressure in the intermediate vacuum space is carried out on the basis of predetermined values representing the pressure in the intermediate vacuum space, and determining the value representing the pressure in the source space is carried out on the basis of predetermined values representing the pressure in the source space. For example, predetermined currents can be stored together with predetermined gas pressures, whereby the current measured in the first operating mode and/or in the second operating mode can be assigned a gas pressure.

In accordance with some embodiments, the method furthermore comprises arranging a sample on the sample holder, and also directing the particle beam onto the sample, and detecting signals generated by the particle beam at the sample during the first operating mode and/or during the second operating mode.

In accordance with some embodiments, the method furthermore comprises switching off the particle beam source and notifying a user of the particle beam system if a pressure in the source space exceeds a predetermined threshold value. For example, if the gas pressure of the high vacuum in the source space increases, a malfunction of the particle beam system may be the cause and the particle beam source can be switched off in order to avoid major damage.

In accordance with some embodiments, the measurement method is such operation of the particle beam system in which a particle-optical image is captured and/or the sample is processed with the particle beam. By way of example, for this purpose, the particle beam is generated by the particle beam source and directed onto the sample in order to cause the desired physical effects for capturing the particle-optical image and/or for processing the sample.

In accordance with some embodiments, the method comprises recording a value representing a current flowing between an emission material of the particle beam source and an acceleration electrode of the particle beam source, and determining the pressure in the source space on the basis of this value. If a gas pressure in the source space is high, for example, many of the particles emitted by the emission material of the particle beam source will interact with the gas situated in the source space, whereby a current flowing between the emission material and the acceleration electrode at high gas pressure becomes low. Determining the pressure in the source space on the basis of the value representing the current flowing between the emission material of the particle beam source and the acceleration electrode of the particle beam source can be carried out during the first operating mode, during which otherwise it would not be possible to determine the pressure in the source space. Consequently, for example, vacuum breaches and other defects can be reliably and quickly detected even during the first operating mode.

In accordance with specific embodiments, the particle beam system comprises a controller configured to cause the particle beam system to carry out the above method.

In accordance with specific embodiments, the particle beam system comprises not more than two ion getter pumps. A plurality of particle beam systems can form a larger overall system; in such a case, for example, not more than two ion getter pumps are provided for each of these particle beam systems.

The above embodiments are explained in greater detail below with reference to figures.

### BRIEF DESCRIPTION OF THE DRAWINGS

FIG. 1 shows a first electron beam microscope suitable for carrying out the method.

FIG. 2 shows a second electron beam microscope suitable for carrying out the method.

FIG. 3 shows a schematic structure of ion getter pumps shown in FIGS. 1 and 2.

FIG. 4 shows a schematic structure of a high-voltage controller shown in FIGS. 1 and 2.

FIG. 5 shows a flowchart showing a method in accordance with an embodiment.

### DETAILED DESCRIPTION

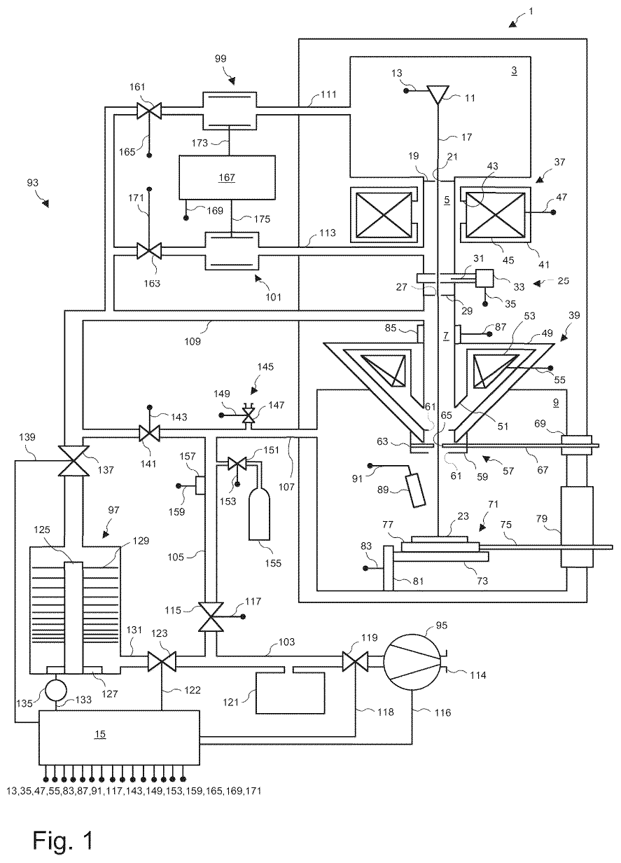

FIG. 1 shows an electron beam microscope 1 comprising a source space 3, a first intermediate vacuum space 5, a second intermediate vacuum space 7 and a sample space 9. An electron beam source 11 is arranged within the source space 3. The electron beam source 11 is electrically connected to a controller 15 via a signal line 13, so that the controller 15 can supply an electrical potential to the electron beam source 11 in order to cause the electron beam source 11 to generate an electron beam 17.

The source space 3 is separated from the first intermediate vacuum space 5 by a stop 19. The stop 19 has an opening 21, through which the electron beam 17 passes when the electron beam 17 is directed onto a sample 23. The first intermediate vacuum space 5 is separated from the second intermediate vacuum space 7 by a protective valve 25 and a stop 27. The stop 27 has an opening 29, through which the electron beam 17 passes when the electron beam 17 is directed onto the sample 23. The stop 19 can for example serve as an acceleration anode of the electron beam source 11 and accelerate the electrons emitted by the electron beam source 11 along the beam path 17. Since the electron beam source 11 emits the electrons at in some instances greatly different angles, not all of the emitted electrons will pass through the opening 21 of the stop 19, but rather will be incident on the stop 19. If the stop 19 is furthermore electrically connected to the controller 15, such as for example for supplying an anode potential via the controller 15, the electrons incident on the stop 19 flow away to the controller 15 via this electrical connection. Consequently, the controller 15 can also measure a current which flows via the signal line 13, the electron beam source 11 and the stop 19 to the controller 15. This current is dependent on a gas pressure prevailing in the source space 3, since the electrons interact with the gas in the source space 3 on the way from the electron beam source 11 to the stop 19. In addition, an increased gas pressure may promote contamination of the emission material, for which reason fewer electrons are emitted and fewer electrons are incident on the stop 19. The controller 15 can thus also determine a gas pressure in the source space 3 by way of the current flowing between the electron beam source 11 and the stop 19.

The protective valve 25 comprises a closure plate 31 and an actuator 33. The actuator 33 is electrically connected to the controller 15 via a signal line 35. If the actuator 33 is operated by the controller 15 via the signal line 35, the actuator moves the closure plate 31 into or out of a beam path of the electron beam 17, whereby a connection of the first intermediate vacuum space 5 to the second intermediate vacuum space 7 is completely separated or opened, respectively. If the protective valve 25 is open and the electron beam 17 is directed onto the sample 23, the electron beam 17 passes through the protective valve 25.

The electron beam microscope 1 furthermore comprises a condenser lens 37 and an objective lens 39. The condenser lens 37 comprises a pole shoe 41 having an opening 43, and also a coil 45. The coil 45 is electrically connected to the controller 15 via a signal line 47. The controller 15 controls the condenser lens 37 by supplying the coil 45 with an electrical current, by virtue of which the coil 45 generates a magnetic field which, at the opening 43, passes from the pole shoe 41 into the beam path of the electron beam 17 and provides a focusing effect on the electron beam 17. The electron beam 17 passes through the condenser lens 37 in the first intermediate vacuum space 5.

The objective lens 39 comprises a pole shoe 49 having an opening 51, and also a coil 53. The coil 53 is electrically connected to the controller 15 via a signal line 55. The controller 15 controls the objective lens 39 by supplying the coil 53 with an electrical current, by virtue of which the coil 53 generates a magnetic field which, at the opening 51, passes from the pole shoe 49 into the beam path of the electron beam 17 and provides a focusing effect on the electron beam 17. The electron beam 17 passes through the objective lens 39 in the second intermediate vacuum space 7.

The second intermediate vacuum space 7 is separated from the sample space 9 by a stop arrangement 57. The stop arrangement 57 comprises a mount 59 having openings 61, and also an exchangeable stop body 63, which is carried by the mount 59. The stop body 63 has a hole 65, the cross-sectional area of which is different from a cross-sectional area of the openings 61 of the mount 59. The stop body 63 can be exchanged by a user of the electron beam microscope 1 by the user removing the stop body 63 through a vacuum lock 69 using a guide mechanism 67 and inserting another stop body into the mount 59 using the guide mechanism 67. It should be noted that FIG. 1 shows the guide mechanism 67, but in some embodiments this guide mechanism is removed from the sample space 9 or is pivoted out laterally from an image field of the electron beam microscope 1 during the directing of the electron beam 17 onto the sample 23.

The electron beam 17 passes through the openings 61 of the mount 59 and the hole 65 of the stop body 63. The electron beam 17 is then incident on the sample 23.

The sample 23 is mounted on a sample mount 73 via a sample guide 71. The sample guide 71 comprises a guide rod 75 and a carrier 77. In this case, the user arranges the sample 23 outside the sample space 9 on the carrier 77 and then brings the sample 23 to the position of the sample holder 73 by moving the guide rod 75 through a lock 79. The guide rod 75 can be detached from the carrier 77 and removed from the sample space 9. As an alternative to the lock 79 or in addition, the electron beam microscope 1 can have an openable door at the sample space 9, through which door the sample 23 can be mounted on the sample mount 73. If, for example, the lock 79 and the door are provided at the sample space 9, samples that are too large for the lock 79 can be brought through the door into the sample space 9.

The electron beam microscope 1 furthermore comprises an actuator 81, the latter making it possible to change a relative position of the sample holder 73 from the stop arrangement 57. For this purpose, the actuator 81 is electrically connected to the controller 15 via a signal line 83.

The electron beam microscope 1 additionally comprises a deflection arrangement 85. In FIG. 1, the deflection arrangement 85 is illustrated as pairs of electrodes, but the deflection arrangement 85 can also be implemented by electromagnetic coils. The deflection arrangement 85 is electrically connected to the controller 15 via a signal line 87. The controller 15 can thus supply electrical potentials to the deflection arrangement 85, so that the deflection arrangement 85 generates an electric field in the beam path of the electron beam 17 and the electron beam 17 is deflected. This enables the electron beam 17 to be directed onto different points of the sample 23.

When the electron beam 17 is incident on the sample 23, various signals are generated at the sample 23, such as for example secondary electrons and backscatter electrons. The electron beam microscope 1 furthermore comprises a detector 89 arranged in the sample space 9, which detector can record such signals and generate corresponding electrical signals. The electrical signals generated by the detector 89 are forwarded to the controller 15 via a signal line 91.

In order to capture a particle-optical image using the electron beam microscope 1, the controller 15 sequentially supplies different potentials to the deflection arrangement 85, whereby the electron beam is directed onto different incidence locations on the sample 23, and stores the signals generated by the detector 89 together with the incidence locations on the sample 23. This process is also referred to hereinafter as scanning of the sample 23.

In the source space 3, the first intermediate vacuum space 5, the second intermediate vacuum space 7 and the sample space 9, vacua of different qualities are generated during the operation of the electron beam microscope 1. A high vacuum is generated in the source space 3, whereas a significantly poorer vacuum is maintained in the sample space 9. For generating the vacua within the source space 3, the first intermediate vacuum space 5, the second intermediate vacuum space 7 and the sample space 9, the electron beam microscope 1 furthermore comprises a pump system 93. The pump system 93 comprises a forepump 95, a turbomolecular pump 97, a first ion getter pump 99 and a second ion getter pump 101. The forepump 95 is for example a positive displacement pump that can attain a forevacuum of 10⁻² mbar. The turbomolecular pump 97 is operated when at least a forevacuum has been attained, since otherwise the turbomolecular pump 97 may be damaged. The turbomolecular pump 97 attains a vacuum of 10⁻⁵ mbar. The first ion getter pump 99 and the second ion getter pump 101 presuppose a vacuum generated by the turbomolecular pump 97 and attain a high vacuum of 10⁻⁶ to 10⁻¹⁰ mbar.

Since the forepump 95 first generates the forevacuum in the source space 3, in the first intermediate vacuum space 5, in the second intermediate vacuum space 7 and in the sample space 9, the forepump 95 is connected to the sample space 9 via a forepump line 103, a transition line 105 and a sample space line 107, so that the forepump 95 can evacuate the sample space 9. Furthermore, the forepump 95 is connected to the second intermediate vacuum space 7 via the forepump line 103, the transition line 105, the sample space line 107 and a turbopump line 109, so that the forepump 95 can evacuate the second intermediate vacuum space 7. The forepump 95 is furthermore connected via the forepump line 103, the transition line 105, the sample space line 107, the turbopump line 109 and ion getter pump lines 111 and 113 to the source space 3 and to the first intermediate vacuum space 5, respectively, in order to be able to evacuate them. The forepump 95 comprises an outlet 114, which ejects gas pumped out of the vacuum spaces to the outside. Operation of the forepump 95 is controlled by the controller 15 via a signal line 116.

In the transition line 105, a separating valve 115 is provided, by which the forepump 95 and the forepump line 103 can be separated from the sample space line 107 and thus from all vacuum spaces. The separating valve 115 is electrically connected to the controller 15 via a signal line 117, so that the controller 15 can cause the forepump 95 to be separated from the vacuum spaces. The transition line 105 and the valve 115 do not have to be provided in the electron beam microscope 1, since the vacua with the forepump 95 can also be generated through the outlet 131 and the switched-off turbomolecular pump 97. Furthermore, a quiescent mode valve 119 electrically connected to the controller 15 via a signal line 118, a buffer volume 121 and a separating valve 123 electrically connected to the controller 15 via a signal line 122 are provided in the forepump line 103. The quiescent mode valve 119 and the buffer volume 121 serve to enable the forepump 95 to be temporarily switched off in order to reduce vibrations and noise. The separating valve 123 is closed by the controller 15 via the signal line 122 in order to protect the turbomolecular pump 97 when the forevacuum has not yet been attained.

The turbomolecular pump 97 comprises a rotor 125, a stator 127, blades 129 and an outlet 131. The stator 127 is electrically connected to the controller 15 via a signal line 133. In order to operate the turbomolecular pump 97, the controller 15 supplies the stator 127 with an electrical current via the signal line 133, whereby the rotor 125 rotates together with the blades 129. As a result of collisions with gas particles, the blades 129 cause the gas particles to be accelerated towards the outlet 131. A current sensor 135 is arranged in the signal line 133, and records the current supplied to the stator 127. Although the stator 127 is shown here without blades, it should be noted that the stator 127 can also have blades which are arranged for example between pairs of the blades 129 shown.

The turbomolecular pump 97 is connected via the turbopump line 109 to the second intermediate vacuum space 7, connected via the turbopump line 109 and the sample space line 107 to the sample space 9, and connected via the turbopump line 109 and the ion getter pump line 111 and the ion getter pump line 113 to the source space 3 and to the first intermediate vacuum space 5, respectively. Furthermore, a separating valve 137 can be provided in the turbopump line 109, the separating valve being electrically connected to the controller 15 via a signal line 139. The controller 15 can then close the separating valve 137 for example while the forepump 95 generates the forevacuum in the vacuum spaces via the transition line 105.

The sample space line 107 furthermore has a separating valve 141, which is electrically connected to the controller 15 via a signal line 143. The separating valve 141 can be closed by the controller 15 in order to separate the sample space line 107 from the turbopump line 109. For example, the separating valve 141 is closed during the measurement method when gas is supplied through a leak valve 151 in the transition line 105 in order to increase the gas pressure in the entire sample space 9. The separating valve 141 can then be closed as desirable in order not to reduce the gas pressure in the sample space 9 as a result of the operation of the turbomolecular pump 97.

A ventilation 145 with a valve 147 is furthermore provided on the sample space line 107. The valve 147 is controllable by the controller 15 via a signal line 149. If the valve 147 is opened, the ventilation 145 connects the interior of the electron beam microscope 1 to the exterior air, so that the electron beam microscope 1 is flooded with air. This can then be carried out for example if damage to the electron beam microscope 1 is detected, the user arranges a new sample 23 in the sample space 9 through the abovementioned alternative or additional door at the sample space 9, or the electron beam microscope 1 is switched off for maintenance work.

The leak valve 151 is provided on the transition line 105, the leak valve being controllable by the controller 15 via a signal line 153. The controller 15 can set a flow of a process gas at the leak valve 151, which gas flows from a supply container 155 or from the ambient air into the transition line. The transition line 105 furthermore has a pressure sensor 157, which records a gas pressure prevailing in the transition line 105 and thus a gas pressure prevailing in the sample space 9 and generates a signal, which is passed on via a signal line 159 to the controller 15.

The ion getter pump line 111 and the ion getter pump line 113 have the ion getter pump 99 and the ion getter pump 101, respectively, and also separating valves 161 and 163. The separating valve 161 is controllable by the controller 15 via a signal line 165. A controller 167 is in communicative contact with the controller 15 via a signal line 169. The separating valve 163 is controllable by the controller 15 via a signal line 171. The controller 167 controls operation of the ion getter pumps 99 and 101. If the vacuum generable by the turbomolecular pump 97 is attained in the source space 3 and in the first intermediate vacuum space 5, the valves 161 and 163 are closed by the controller 15 and a high voltage is supplied by the controller 167 to the ion getter pumps 99 and 101 via signal lines 173 and 175 in order to generate the high vacuum in the source space 3 and in the first intermediate vacuum space 5. The controller 15 and the controller 167 can also be designed as a common controller that controls both the valves 161 and 163 and also the supply of high voltage. The control of the respective components of the electron beam microscope 1 can be divided in any desired way between the controller 15 and the controller 167.

The valves 115, 119, 123, 137, 141, 147, 151, 161 and 163 shown in FIG. 1 can be magnetic valves, for example. The valves 115, 119, 123, 137, 141, 147, 151, 161 and 163 can also be other valves as long as they are controllable by the controllers 15 and 167.

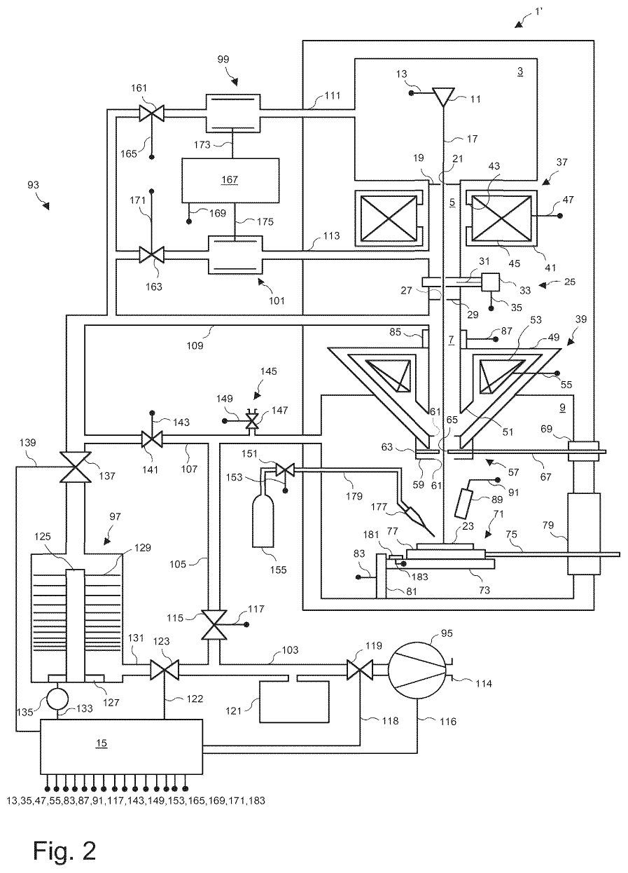

FIG. 2 shows a second electron beam microscope 1′ suitable for carrying out the method. In FIG. 2, components and functions are provided with corresponding reference signs. For components and functions whose reference sign in FIG. 2 is the same as the one used in FIG. 1, reference is made to the above description of the component or function, respectively.

The electron beam microscope 1′ shown in FIG. 2 differs from the electron beam microscope 1 shown in FIG. 1 in that the flow of the process gas is not supplied to the transition line 105, but rather is supplied directly to the sample 23 with the aid of a needle 177. The needle 177 is connected to the supply container 155 via a gas supply line 179 and the leak valve 151, so that the process gas is supplied from the supply container 155 or the ambient air directly to the sample 23. In the electron beam microscope 1′, a pressure sensor 181 is mounted on the sample holder 73 and is electrically connected to the controller 15 via a signal line 183. This arrangement of the pressure sensor 181 means that the pressure in the vicinity of the needle 177 is recorded and is not distorted by a large distance with respect to the local supply of the process gas. It should furthermore be noted that in the case of a local supply of the process gas via the needle 177, the separating valve 141 can be open during the measurement method.

It should be noted that the particle beam system is not restricted to the electron beam microscope 1. For example, the particle beam system can also be an ion beam system that generates a particle beam composed of ionized atoms. The particle beam system can additionally be integrated in a larger system, such as for example in an FIB-SEM, which generates both an ion beam and an electron beam. By way of example, on such an FIB-SEM particle beam system, two ion getter pumps are provided per particle beam generated.

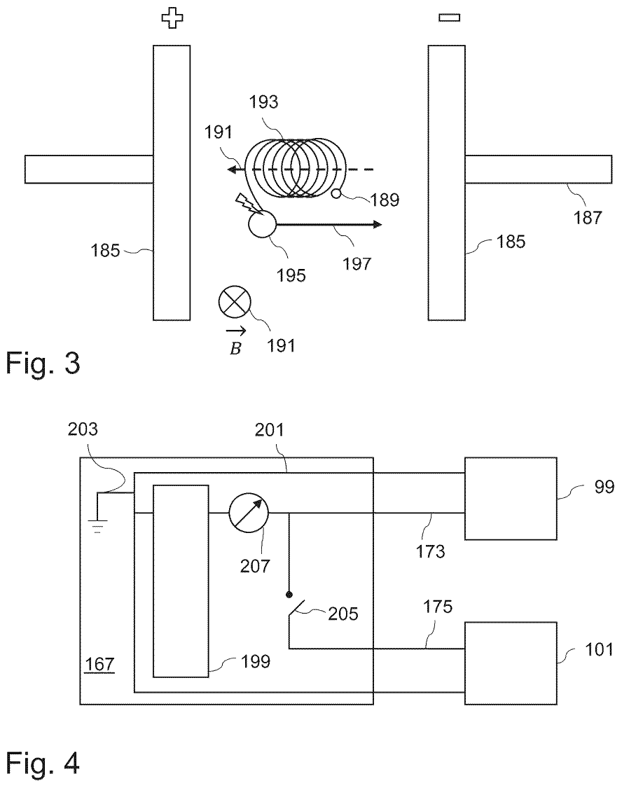

FIG. 3 shows a schematic structure of the ion getter pumps 99 and 101 shown in FIGS. 1 and 2. The ion getter pumps 99 and 101 each comprise two electrodes 185, wherein one of the electrodes serves as an anode and the other electrode serves as a cathode. The electrodes 185 are secured by way of mounts 187, which in the case shown in FIG. 3 comprise the signal line 173 and the signal line 175, respectively. For example, the mounts 187 can consist of a conductive material.

By virtue of the potentials supplied to the electrodes 185, an electric field is generated between the electrodes. In addition, a magnetic field is generated perpendicular to the electric field, the direction of which magnetic field runs perpendicular to the plane of the drawing and is represented by a cross 191 in FIG. 3. This magnetic field can be generated by permanent magnets (not shown).

An electron 189 having a velocity component parallel to the electric field generated by the electrodes 185 is deflected by the magnetic field onto a spiral path 193. The electron 189 moves on the spiral path 193 along a direction 191 towards the anode. The deflection of the electron 189 on the spiral path 193 causes the electron 189 to remain as long as possible in a concentrated region between the electrodes 185. This increases a probability of the electron 189 interacting with a gas particle 195 and positively or negatively ionizing the gas particle 195. The positively ionized gas particle 195 is then accelerated in a direction 197 towards the cathode, is incident on the cathode and is held there permanently or temporarily by chemical or physical binding forces. In this case, the positively ionized gas particle 195, by virtue of its high impulse, can penetrate into the material of the cathode or else be buried by atomizing cathode material. The positively ionized gas particle 195 moves substantially in a straight line to the cathode. The negatively ionized gas particle 195 is accelerated counter to the direction 197 towards the anode and is incident on the anode. The explanation given above on the basis of the example of the incidence of the gas particle 195 on the cathode is similarly applicable to the incidence of the gas particle 195 on the anode. Consequently, the ion getter pumps 99 and 101 can further reduce the gas pressure in the source space 3 and the first intermediate vacuum space 5 via ionization and retaining of gas particles. For example, during the operation of the ion getter pumps 99 and 101, the valves 161 and 163 can be permanently closed in order that the pressure can be further reduced compared to the pressure prevailing in the turbopump line 109.

FIG. 4 shows a schematic structure of the controller 167 shown in FIGS. 1 and 2. The controller 167 comprises a high-voltage source 199, which is electrically connected to the ion getter pump 99 via the signal line 173 and to the ion getter pump 101 via the signal line 175. The high-voltage source 199 generates a high voltage between the signal line 173 and ground 203, and also between the signal line 175 and ground 203. The ion getter pumps 99 and 101 are in each case furthermore connected to ground 203 via ground lines 201.

The controller 167 additionally comprises a switch 205, which can disconnect the electrical connection of the ion getter pump 101 to the high-voltage source 199 via the signal line 175. Furthermore, the controller 167 comprises a current sensor 207, which records a current supplied from the high-voltage source 199 to the ion getter pumps 99 and 101. In a case in which the switch 205 is closed, a total current supplied to the first ion getter pump 99 and the second ion getter pump 101 is recorded by the current sensor 207. In a case in which the switch 205 is open, a current supplied to the first ion getter pump 99 is recorded by the current sensor 207.

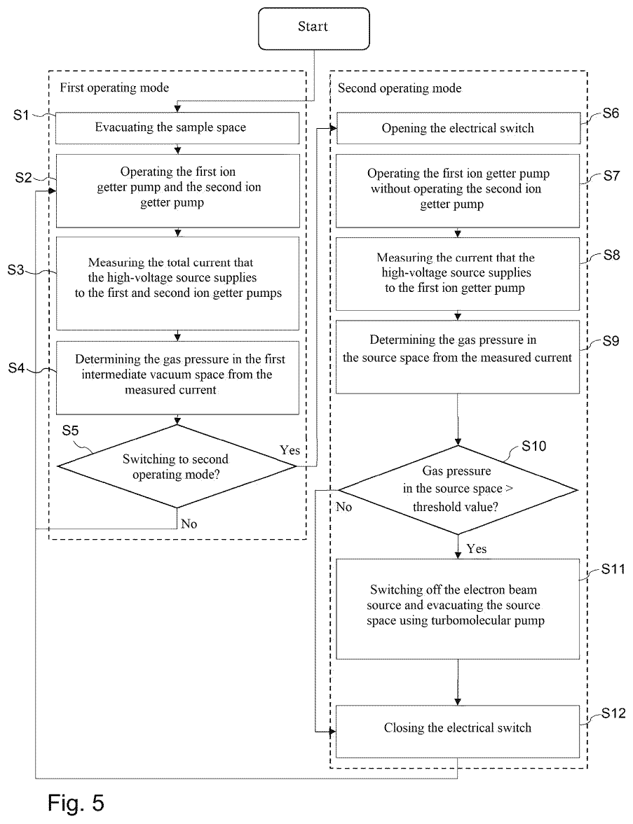

The proposed method in accordance with one embodiment is described in detail below. FIG. 5 shows a flowchart showing the method in accordance with one embodiment. The flowchart in FIG. 5 shows steps S1 to S12, wherein steps S1 to S5 form the first operating mode and steps S6 to S12 form the second operating mode.

In the first operating mode, the controller 15 begins to evacuate the sample space 9. In a case in which there is not yet at least a forevacuum prevailing in the sample space 9, in the first and second intermediate vacuum spaces 5, 7 and in the source space, the controller 15 begins to close the separating valves 123 and 137, open the quiescent mode valve 119 and the separating valves 115 and 141 and operate the forepump 95. Alternatively, the controller 15 can also keep the separating valves 123 and 137 open in order to generate the forevacuum through the turbomolecular pump 97. This is desirable for example if no transition line 105 is provided. In addition, the controller 15 opens the separating valves 161 and 163 via the controller 167, so that the source space 3 and the first intermediate vacuum space are also evacuated by the forepump 95. For example, if a pressure corresponding to the forevacuum is recorded by the pressure sensor 157, the controller 15 closes the separating valve 115 and opens the separating valves 123 and 137.

The controller 15 then operates the turbomolecular pump 97 in order to evacuate the sample space 9, the first and second intermediate vacuum spaces 5, 7 and the source space 3 with the separating valves 141, 161 and 163 open. If a predetermined low gas pressure is recorded by the pressure sensor 157, the controller 15 closes the separating valves 161 and 163. The closing of the separating valves 161 and 163 can also be carried out later. For example, the ion getter pumps 99 and 101 can firstly be put into operation and afterwards the separating valves 161 and 163 can be closed.

In step S2, the controller 167 operates the first ion getter pump 99 and the second ion getter pump 101 by generating a high voltage via the high-voltage source 199 with the switch 205 closed and supplying the high voltage to the ion getter pumps 99 and 101. For example, the ion getter pumps 99, 101, the turbomolecular pump 97 and the forepump 95 are operated in such a way that a gas pressure in the source space 3 is lower than a gas pressure in the first intermediate vacuum space 5, the gas pressure in the first intermediate vacuum space 5 is lower than the gas pressure in the second intermediate vacuum space 7, and the gas pressure in the second intermediate vacuum space 7 is lower than the gas pressure in the sample space 9.

While the first ion getter pump 99 and the second ion getter pump 101 are operated, in step S3 the controller 167 records the total current provided by the high-voltage source 199, to put it more precisely the current supplied to the first ion getter pump 99 and the second ion getter pump 101.

Since the gas pressure in the first intermediate vacuum space 5 is significantly greater than the gas pressure in the source space 3, the current of the second ion getter pump 101 is significantly greater than the current of the first ion getter pump 99. In accordance with specific embodiments, the current of the ion getter pump 101 can be greater than 10 times, such as 25 times, for example 100 times, for example 1000 times, the current of the ion getter pump 99. Accordingly, for example disregarding the current of the first ion getter pump 99, in step S4, the gas pressure in the first intermediate vacuum space 5 can be determined sufficiently accurately on the basis of the recorded current.

As mentioned above, in step S3 the controller can furthermore record a current flowing between the emission material of the electron beam source 11 and the stop 19. In step S4, the controller 15 can then furthermore determine a gas pressure in the source space 3 on the basis of the current flowing between the emission material of the electron beam source 11 and the stop 19. Such a determination can prevent defects from not being taken into account if such defects occur during the first operating mode, in which the gas pressure in the source space 3 cannot be determined by way of that of the first ion getter pump 99.

The second operating mode is started from the first operating mode. For this purpose, a decision is made in step S5 as to whether switching from the first operating mode to the second operating mode ought to take place. For example, every 1 minute, such as every 10 minutes, for example every 60 minutes, for example every 3 hours, for example every 12 hours, for example every 24 hours, for example every 3 days, a decision can be made that switching to the second operating mode ought to take place, wherein the method continues with step S6 in this case. If it is determined that switching to the second operating mode ought not to take place, both ion getter pumps will continue to be operated, as described in step S2.

The second operating mode begins with step S6. In step S6, the controller 167 opens the electrical switch 205 in order to disconnect the second ion getter pump 101 from the high-voltage source 199.

The controller 15 can operate the turbomolecular pump 97 during the entire method. It should be noted that the turbomolecular pump 97 can be operated with valves 141 and 25 open or closed. Switching to the second operating mode can take place at any time with valve 25 closed, even if the sample space 9 is no longer evacuated.

In step S7, the controller 167 operates only the first ion getter pump 99, without operating the second ion getter pump 101. For this purpose, the switch 205 is open, whereby the second ion getter pump 101 is not supplied with high voltage or current.

In step S8, the controller 167 then records the current supplied to the first ion getter pump 99 by way of the current sensor 207. Since the current provided by the high-voltage source 199 is exclusively the current supplied to the first ion getter pump 101, the gas pressure in the source space can then be determined from the recorded current in step S9. For example, in steps S4 and S9, the gas pressures can be determined by a procedure in which various gas pressures together with corresponding currents are stored in advance and a gas pressure corresponding to the measured current is selected from the stored data in steps S4 and S9. Alternatively or additionally, for example, a predetermined functional relationship between the current and the gas pressure can also be stored, on the basis of which the gas pressures of the first intermediate vacuum space 5 and of the source space 3 are determined in steps S4 and S9.

In step S10, the controller 15 compares the gas pressure in the source space 3 with a predetermined threshold value. If the gas pressure in the source space 3 is greater than the predetermined threshold value, the controller 15 continues with step S11. If the gas pressure in the source space 3 is not greater than the predetermined threshold value, the method continues with step S12.

In step S11, the controller 15 switches off the electron beam source 11. In such a case, a malfunction of the electron beam microscope 1 may be present, which is why switching off the particle beam source 11 can prevent additional damage. In addition, the controller 15 can open the valves 161 and 163 via the signal lines 165 and 171 and thus evacuate the source space 3 and the first intermediate vacuum space 5 via the turbomolecular pump 97.

In step S12, the controller 167 closes the electrical switch 205, so that the second ion getter pump 101 is electrically connected to the high-voltage source 199 again, whereby the controller 167 switches back to the first operating mode. For example, when the electrical switch 205 is closed, a transition is made to step S2, since the high voltage is then supplied to both ion getter pumps 99, 101.

Steps S6 to S12 can be carried out quickly enough to sufficiently minimize a deterioration of the vacuum prevailing in the first intermediate vacuum space 5 on account of the switched-off second ion getter pump 101. In accordance with specific embodiments, steps S7 to S12 are carried out within 0.1 second, such as 1 second, for example 10 seconds. As long as the protective valve 25 is closed or the pressure in the source space 3 and in the first intermediate vacuum space 5 is sufficiently low, steps S6 to S12 can be carried out independently of the operation of the further components of the electron beam microscope 1. The switching between the first operating mode and the second operating mode can be carried out for example every 1 minute, such as every 10 minutes, for example every 60 minutes, for example every 3 hours, for example every 12 hours, for example every 24 hours, for example every 3 days.

It should be noted that the second operating mode can also be carried out for longer than described above. For example, the second operating mode can be used to monitor a change in the gas pressure in the source space 3. For this purpose, steps S6 to S12 are carried out over a period of for example 1 minute, 10 minutes, 60 minutes, 3 hours, 12 hours, 24 hours or 3 days. In this case, while steps S6 to S12 are carried out, the first intermediate vacuum space 5, the second intermediate vacuum space 7 and the sample space 9 are evacuated by the turbomolecular pump 97. For example, for this purpose the controller 15 opens the valve 163 before or after opening the switch 205 in step S6.

The above-described method for operating the electron beam microscope 1, 1′ makes it possible to operate both ion getter pumps 99, 101 with a common high-voltage source 199, wherein determining the gas pressure in the source space 3 and the gas pressure in the first intermediate vacuum space 5 by way of the current supplied to the ion getter pumps 99, 101 is additionally possible. Consequently, a large number of components of the vacuum system can be obviated and a simplified vacuum system can be provided.

What is claimed is:

1. A method of operating a particle beam system comprising a particle beam source, an source space, an sample space, an intermediate vacuum space, a first ion getter pump, a second ion getter pump and a high-voltage source, the intermediate vacuum space separated from the source space and connected thereto via a first opening, the intermediate vacuum separated from the sample space and connected thereto via a second opening, the particle beam system configured so that in a measurement method a particle beam generated by the particle beam source and directed onto a sample in the sample space passes through the first and second openings, the method comprising:
in a first mode:
evacuating the sample space;
operating the first and second ion getter pumps with the high-voltage source to evacuate the source space and the intermediate vacuum space so that a pressure in the source space is less than a pressure in the intermediate vacuum space and so that the pressure in the intermediate vacuum space is less than a pressure in the sample space; and
measuring a current supplied from the high-voltage source to the first and second ion getter pumps and determining a value representing the pressure in the intermediate vacuum space based on measured current; and
in a second mode:
evacuating the sample space;
operating the first ion getter pump with the high-voltage source to evacuate the source space without operating the second ion getter pump with the high-voltage source; and
measuring a current supplied from the high-voltage source to the first ion getter pump and determining a value representing the pressure in the source space based on the measured current.

2. The method of claim 1, further comprising:
opening a switch so that the second ion getter pump is disconnected from the high-voltage source in the second operating mode; and
closing the switch so that the second ion getter pump is connected to the high-voltage source in the first operating mode.

3. The method of claim 1, wherein the particle beam system further comprises a first valve vacuum connected between the intermediate vacuum space and a pump that evacuates the sample space, wherein the first valve is closed in the first operating mode, and the first valve is open in the second operating mode.

4. The method of claim 1, wherein:
determining the value representing the pressure in the intermediate vacuum space is performed based on predetermined values representing the pressure in the intermediate vacuum space; and
determining the value representing the pressure in the source space is performed based on predetermined values representing the pressure in the source space.

5. The method of claim 1, further comprising:
arranging a sample in the sample space; and
directing the particle beam onto the sample and detecting signals generated by the particle beam at the sample during the first operating mode.

6. The method of claim 5, further comprising detecting signals generated by the particle beam at the sample during the second operating mode.

7. The method of claim 1, further comprising:
arranging a sample in the sample space; and
directing the particle beam onto the sample and detecting signals generated by the particle beam at the sample during the second operating mode.

8. The method of claim 1, further comprising switching off the particle beam source and notifying a user of the particle beam system when a pressure in the source space exceeds a predetermined threshold value.

9. The method of claim 1, further comprising performing the measurement method.

10. The method of claim 9, wherein the measurement method is performed to capture a particle-optical image of the sample and/or to process the sample with the particle beam.

11. The method of claim 1, further comprising:
opening a switch so that the second ion getter pump is disconnected from the high-voltage source in the second operating mode; and
closing the switch so that the second ion getter pump is connected to the high-voltage source in the first operating mode,
wherein the particle beam system further comprises a first valve vacuum connected between the intermediate vacuum space and a pump that evacuates the sample space, wherein the first valve is closed in the first operating mode, and the first valve is open in the second operating mode.

12. The method of claim 11, wherein:
determining the value representing the pressure in the intermediate vacuum space is performed based on predetermined values representing the pressure in the intermediate vacuum space; and
determining the value representing the pressure in the source space is performed based on predetermined values representing the pressure in the source space.

13. The method of claim 12, further comprising:
arranging a sample in the sample space; and
directing the particle beam onto the sample and detecting signals generated by the particle beam at the sample during the first operating mode and/or during the second operating mode.

14. The method of claim 13, further comprising switching off the particle beam source and notifying a user of the particle beam system when a pressure in the source space exceeds a predetermined threshold value.

15. The method of claim 14, further comprising performing the measurement method.

16. The method of claim 15, wherein the measurement method is performed to capture a particle-optical image of the sample and/or to process the sample with the particle beam.

17. The method of claim 1, further comprising:
opening a switch so that the second ion getter pump is disconnected from the high-voltage source in the second operating mode; and
closing the switch so that the second ion getter pump is connected to the high-voltage source in the first operating mode,
wherein:
determining the value representing the pressure in the intermediate vacuum space is performed based on predetermined values representing the pressure in the intermediate vacuum space; and
determining the value representing the pressure in the source space is performed based on predetermined values representing the pressure in the source space.

18. The method of claim 1, further comprising:
opening a switch so that the second ion getter pump is disconnected from the high-voltage source in the second operating mode;
closing the switch so that the second ion getter pump is connected to the high-voltage source in the first operating mode;
arranging a sample in the sample space; and
directing the particle beam onto the sample and detecting signals generated by the particle beam at the sample during the first operating mode and/or during the second operating mode.

19. The method of claim 1, further comprising:
opening a switch so that the second ion getter pump is disconnected from the high-voltage source in the second operating mode;
closing the switch so that the second ion getter pump is connected to the high-voltage source in the first operating mode; and
switching off the particle beam source and notifying a user of the particle beam system when a pressure in the source space exceeds a predetermined threshold value.

20. A particle beam system, comprising:
a particle beam source;
a source space;
a sample space;
an intermediate vacuum space separated from the source space and connected thereto via a first opening, the intermediate vacuum space separated from the sample space and connected thereto via a second opening;
a first ion getter pump configured to evacuate the source space;
a second ion getter pump configured to evacuate the intermediate vacuum space;
a high-voltage source; and
a controller configured to control the particle beam system to perform a method comprising:
in a first mode:
evacuating the sample space;
operating the first and second ion getter pumps with the high-voltage source to evacuate the source space and the intermediate vacuum space so that a pressure in the source space is less than a pressure in the intermediate vacuum space and so that the pressure in the intermediate vacuum space is less than a pressure in the sample space; and
measuring a current supplied from the high-voltage source to the first and second ion getter pumps and determining a value representing the pressure in the intermediate vacuum space based on measured current; and
in a second mode:
evacuating the sample space;
operating the first ion getter pump with the high-voltage source to evacuate the source space without operating the second ion getter pump with the high-voltage source; and
measuring a current supplied from the high-voltage source to the first ion getter pump and determining a value representing the pressure in the source space based on the measured current,
wherein the particle beam system is configured so that in a measurement method a particle beam generated by the particle source and directed onto a sample in the sample space passes through the first and second openings.
